(19) United States
(12) Patent Application Publication
(10) Pub. No.: US 2013/0025679 A1
(43) Pub. Date: Jan. 31, 2013

(54) SOLAR CELL MODULE AND SOLAR POWER GENERATION DEVICE

(71) Applicants: Tsuyoshi Maeda, Osaka (JP); Hidefumi Yoshida, Osaka (JP); Tsuyoshi Kamada, Osaka (JP)

(72) Inventors: Tsuyoshi Maeda, Osaka (JP); Hidefumi Yoshida, Osaka (JP); Tsuyoshi Kamada, Osaka (JP)

(73) Assignee: SHARP KABUSHIKI KAISHA, Osaka (JP)

(21) Appl. No.: 13/497,463

(22) PCT Filed: Sep. 2, 2010
(86) PCT No.: PCT/JP10/65046

§ 371 Date: Mar. 21, 2012

(30) Foreign Application Priority Data
Nov. 25, 2009 (JP) 2009-267860

(51) Int. Cl. H01L 31/0232; H01L 31/18

(52) U.S. Cl. 136/257; 136/252; 438/65; 257/E31.127

(57) ABSTRACT

A solar cell module (10) includes: a low refractive index material layer (1) provided on an object (4); a high refractive index material layer (2), provided on the low refractive index material layer (1), which has a higher refractive index than the low refractive index material layer (1); and a solar cell element (3) provided on that surface of the high refractive index material layer (2) which intersects that surface (counter surface facing the low refractive index material layer (1)) of the high refractive index material layer (2) which is in contact with the low refractive index material layer (1). Further, the high refractive index material layer (2) contains a fluorescent material dispersed therein. Thus, light guided through the high refractive index material layer (2) is reflected at the interface between the high refractive index material layer (2) and the low refractive index material layer (1) and the interface between the low refractive index material layer (1) and an air layer, and is efficiently focused onto the solar cell element (3). This makes it possible to inexpensively and easily produce a solar cell module that has a high degree of freedom in design and that can be installed on a curved surface etc. without limitations of installation locations.

### TECHNICAL FIELD

The present invention relates to a solar cell module and a solar power generation device including the solar cell module.

### BACKGROUND ART

For the purpose of efficient use of solar energy, a typical solar power generation device has conventionally been used with solar panels laid all over a surface to face the sun. Such solar panels are generally constituted by opaque semiconductors and therefore cannot be placed on top of each other. Therefore, in order to collect sufficient sunlight, it is necessary to use large-area solar panels, which require a large installation area.

As a technology for efficiently using solar energy while achieving a reduction in area of a solar panel, Patent Literature 1 discloses a technique for, by providing a solar cell on an end face of a fluorescent plate with a fluorescent material dispersed therein, causing sunlight incident on the fluorescent plate to be focused onto the solar cell and thereby increasing the efficiency of power generation. Further, Patent Literature 2 discloses a solar energy converter having a solar cell provided on a side face of a translucent layer obtained by joining a translucent substrate containing a fluorescent material to a light-receiving surface of a heat collecting board.

### CITATION LIST

### Patent Literature 1

Japanese Utility Model Application Publication, Jitsukaisho, No. 61-136559 U (Publication Date: Aug. 25, 1986)

### Patent Literature 2

Japanese Patent Application Publication, Tokukaisho, No. 58-49860 A (Publication Date: Mar. 24, 1983)

### SUMMARY OF INVENTION

### Technical Problem

The technologies disclosed in Patent Literatures 1 and 2 do not require large-area solar panels for collecting sunlight. However, because the technologies use a large number of substrates with a fluorescent material mixed thereinto, production costs grow high. Also, because the technologies use light guide plates such as acrylic plates to focus sunlight onto the solar cells, it is difficult, for example, to place such a device on a curved surface etc., so that the scope of application is limited.

Therefore, there is a demand for the development of a solar cell module that can be easily and inexpensively produced while requiring less space, that has a high degree of freedom in design, and that can be placed on a curved surface etc. without limitations of installation locations.

The present invention is invented in view of the above problem, and its object is to provide (i) a solar cell module that can be easily and inexpensively produced, that has a high degree of freedom in design, and that can be placed on a curved surface etc. without limitations of installation locations, and (ii) a solar power generation device including such a solar cell module.

### Solution to Problem

In order to solve the foregoing problems, a solar cell module according to the present invention includes: a low refractive index material layer provided on an object; a high refractive index material layer, provided on the low refractive index material layer, which has a higher refractive index than the low refractive index material layer and which contains a fluorescent material; and a solar cell element provided on an intersecting surface of the high refractive index material layer, the intersecting surface intersecting a counter surface of the high refractive index material layer, the counter surface facing the low refractive index material layer.

With the above configuration, the solar cell module is configured such that the high refractive index material layer having a higher refractive index than the low refractive index material layer and containing a fluorescent material is provided on the low refractive index material layer provided on the object. Therefore, because these layers can be formed, for example, by coating the object, the solar cell module can be suitably placed on a curved surface etc. without limitations of installation locations. Furthermore, since the solar cell element is provided on that end face of the high refractive index material layer which intersects the light-collecting surface, the solar cell module can be inexpensively produced which is small in area but sufficient in power generation efficiency.

Additionally, because the refractive index relationship between the high refractive index material layer and the low refractive index material layer is under control, light from the fluorescent material excited by sunlight can be efficiently guided through the high refractive index material layer. Therefore, since the solar cell module is installed by forming the layers by coating building walls, roof tiles, automobile bodies, etc., a highly efficient solar power generation system can be achieved.

A solar power generation device according to the present invention includes such a solar cell module as that described above. Since the solar power generation device according to the present invention includes such a solar cell modules as that described above, the solar power generation device can efficiently convert solar energy into electrical power on building walls, roof tiles, automobile bodies, etc.

A method according to the present invention for producing a solar cell module includes: a low refractive index material layer forming step of forming a low refractive index material layer by coating an object with a low refractive index material; a high refractive index material layer forming step of forming a high refractive index material layer by coating the low refractive index material layer with a high refractive index material having a higher refractive index than the low refractive index material and containing a fluorescent material; and an attaching step of attaching a solar cell element to an intersecting surface of the high refractive index material layer, the intersecting surface intersecting a counter surface of the high refractive index material layer, the counter surface facing the low refractive index material layer.

Alternatively, a method according to the present invention for producing a solar cell module includes: an attaching step of attaching a solar cell element onto an object; a low refractive index material layer forming step of, subsequent to the attaching step, forming a low refractive index material layer by coating the object with a low refractive index material; and a high refractive index material layer forming step of forming a high refractive index material layer by coating the low refractive index material with a high refractive index material having a higher refractive index than the low refractive index material and containing a fluorescent material, in the low refractive index material layer forming step, the low refractive index material layer being formed in such a manner that an intersecting surface of the solar cell element and an end face of the low refractive index material are in contact with each other, the intersecting surface intersecting that surface of the solar cell element which is in contact with the object, in the high refractive index material layer forming step, the high refractive index material layer being formed in such a manner that a light-receiving surface of the solar cell element and an end face of the high refractive index material layer are in contact with each other.

With the above configuration, because the low refractive index material layer and the high refractive index material layer can be formed by coating the object with the materials during the production of the solar cell module, the solar cell module can be suitably placed on a curved surface etc. without limitations of installation locations. The solar cell module can also be produced easily and inexpensively.

### Advantageous Effects of Invention

A solar cell module according to the present invention includes: a low refractive index material layer provided on an object; a high refractive index material layer, provided on the low refractive index material layer, which has a higher refractive index than the low refractive index material layer and which contains a fluorescent material; and a solar cell element provided on an intersecting surface of the high refractive index material layer, the intersecting surface intersecting a counter surface of the high refractive index material layer, the counter surface facing the low refractive index material layer. This makes it possible to easily and inexpensively produce a solar cell module that has a high degree of freedom in design and that can be placed on a curved surface etc. without limitations of installation locations.

### BRIEF DESCRIPTION OF DRAWINGS

FIG. 1 is a cross-sectional view showing a solar cell module according to an embodiment of the present invention.

FIG. 2 is a cross-sectional view showing a solar cell module according to another embodiment of the present invention.

FIG. 3 is a cross-sectional view showing a solar cell module according to another embodiment of the present invention.

### DESCRIPTION OF EMBODIMENTS

### Embodiment 1

(Solar Cell Module 10)

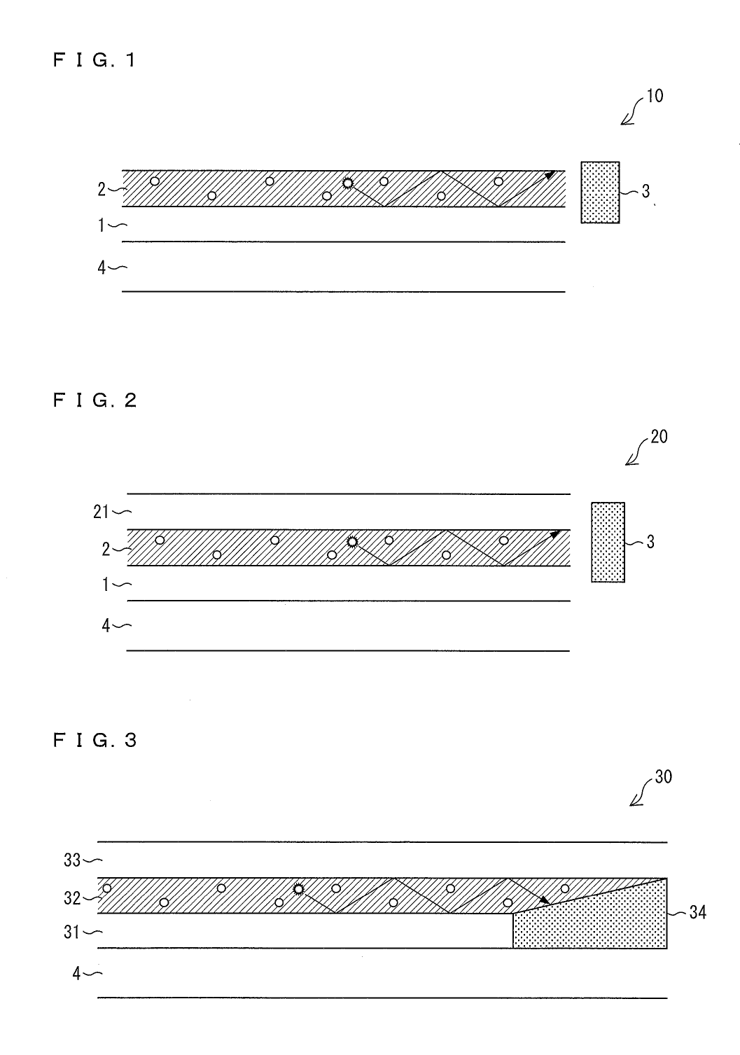

An embodiment of a solar cell module 10 according to the present invention is described below with reference to FIG. 1. FIG. 1 is a cross-sectional view showing the solar cell module 10. As shown in FIG. 1, the solar cell module 10 includes: a low refractive index material layer 1 provided on a surface of an object 4; a high refractive index material layer 2, provided on the low refractive index material layer 1, which has a higher refractive index than the low refractive index material layer 1 and which has a higher refractive index than air; and a solar cell element 3 provided on that surface of the high refractive index material layer 2 which intersects that surface (counter surface facing the low refractive index material layer 1) of the high refractive index material layer 2 which is in contact with the low refractive index material layer 1. Also, the high refractive index material layer 2 contains a fluorescent material dispersed therein. It should be noted that in FIG. 1, the object 4 is present on a surface of the low refractive index material layer 1 opposite that surface of the low refractive index material layer 1 which is in contact with the high refractive index material layer 2.

The low refractive index material layer 1 is provided on the surface of the object 4 on which the solar cell module 10 is installed. The high refractive index material layer 2 is provided on a surface of the low refractive index material layer opposite that surface of the low refractive index material layer which is in contact with the object 4. The fluorescent material dispersed in the high refractive index material layer 2 gets excited by sunlight having entered the high refractive index material layer 2, and the exciting light is guided through the high refractive index material layer 2 while being repeatedly reflected at the interface between the high refractive index material layer 2 and the low refractive index material layer 1 and is thus focused onto the solar cell element 3. This allows efficient collection of sunlight, thereby increasing the power generation efficiency of the solar cell module 10.

The object 4, on which the solar cell module 10 is installed, is an object that is irradiated with sunlight, and can be an object that is placed mainly in an outdoor location. Examples of such an object 4 include, but are not limited to, building walls, automobile bodies, house roofs, etc.

(Low Refractive Index Material Layer 1)

The low refractive index material layer 1 reflects light from the high refractive index material layer 2 at the interface between the low refractive index material layer 1 and the high refractive index material layer 2 due to the difference in refractive index. Also, the low refractive index material layer 1 prevents the light from the high refractive index material layer 2 from being absorbed by the object 4. Examples of a material for the low refractive index material layer 1 include, but are not limited to, a silica particle dispersion polymer, a resin layer having an air gap that is not larger than the wavelength of light, etc. In the case of installation of the solar cell module 10 on an object 4 that is used mainly in an outdoor location, a material that is not damaged by exposure to wind and rain is selected.

The low refractive index material layer 1 can be formed by coating the object 4 with a low refractive index material (low refractive index material layer forming step). Alternatively, the low refractive index material layer 1 may be formed by forming a layer of a low refractive index material in advance and then attaching the layer onto the object 4 with an adhesive or the like. Examples of a method for coating the object 4 with the low refractive index material includes nebulizing the low refractive index material with a nebulizer such as a spray, directly applying the low refractive index material for coating, etc.

Since the refractive index of the low refractive index material layer 1 is lower than that of the high refractive index material layer 2, the density of the low refractive index material in the low refractive index material 1 may be so low that there are holes or spaces inside of the low refractive index material layer. Therefore, it is also possible to suitably form the low refractive index material layer 1 by nebulizing a low refractive index material with a nebulizer for coating. The low refractive index material layer 1 is formed by curing the low refractive index material with which the object 4 has been coated.

It is preferable that the low refractive index material layer 1 have a thickness in the range of 1 to 10000 μm or, more preferably, in the range of 10 to 1000 μm. This allows the low refractive index material layer 1 to be easily formed with use of a conventionally known method.

(High Refractive Index Material Layer 2)

The high refractive index material layer 2 is configured such that light from the fluorescent material excited by light incident on a surface (light-collecting surface) of the high refractive index material layer 2 opposite that surface of the high index material layer 2 which is in contact with the low refractive index material layer 1 is guided through the high index material layer 2 and focused onto the solar cell element 3 provided at an end of the high refractive index material layer 2. The light guided through the high refractive index material layer 2 gets reflected at the interface between the high refractive index material layer 2 and the low refractive index material layer 1. Furthermore, when the light guided through the high refractive index material layer is incident on the light-collecting surface of the high refractive index material layer 2, the light-collecting surface reflects the light since the refractive index of the high refractive index material layer 2 is higher than that of air. This allows the light guided through the high refractive index material layer 2 to be efficiently focused onto the solar cell element.

Examples of a high refractive index material for the high refractive index material layer 2 include, but are not limited to, epoxy resin, acrylic resin, etc. In the case of installation of the solar cell module 10 on an object 4 that is used mainly in an outdoor location, a material that is not damaged by exposure to wind and rain is selected.

The high refractive index material layer 2 can be formed by coating the low refractive index material layer 1 with a high refractive index material containing a fluorescent material (high refractive index material layer forming step). Alternatively, the high refractive index material layer 2 can be formed by forming a layer of a high refractive index material in advance and then attaching the layer onto the low refractive index material layer 1 with an adhesive or the like. Examples of a method for coating the low refractive index material layer 1 with the high refractive index material layer 2 include nebulizing the high refractive index material with a nebulizer such as a spray for coating, applying the high refractive index material for coating, etc. Since the refractive index of the high refractive index material layer 2 is higher than that of the low refractive index material layer 1, it is preferable that the density of the high refractive index material in the high refractive index material layer 2 be high. Therefore, it is preferable that the high refractive index material layer 2 be provided in the form of a dense layer by applying the high index material onto the low refractive index material layer 1. The high refractive index material layer 2 is formed by curing the high refractive index material with which the low refractive index material layer 1 has been coated.

It is preferable that the high refractive index material layer 2 have a thickness in the range of 100 to 20000 μm or, more preferably, in the range of 1000 to 10000 μm. This makes it possible to form a light guide layer with a fluorescent material evenly mixed therein.

It is possible to cause the high refractive index material layer 2 to contain a variety of fluorescent materials. Examples of such fluorescent materials are rare-earth metal complexes, and examples of such rare-earth metal complexes include, but are not limited to, sialon fluorescent materials such as a [Tb(bpy)2]C13 metal complex, a [Tb(terpy)2]C13 metal complex, a [Eu(phen)2]C13 metal complex, and Ca-α-SiAlON:Eu. As a fluorescent material to be dispersed in the high refractive index material layer 2, it is also possible to use (i) a hydrochloride or sulfate salt of a rare-earth metal such as samarium, terbium, europium, gadolinium, or dysprosium, (ii) a transition metal acid salt such as calcium molybdate or calcium tungstate, (iii) an aromatic hydrocarbon such as benzene and naphthalene, (iv) a phthalein pigment such as eosin and fluorescein, or (v) the like.

It is preferable that the fluorescent material dispersed in the high refractive index material layer 2 have a particle size in the range of 5 to 10 μm. This makes it possible to achieve efficient fluorescence emission. Also, it is preferable that the content of the fluorescent material in the high refractive index material layer 2 be less than or equal to 10% by weight. This makes it possible to suppress multiple scattering of the fluorescent material and thereby achieve efficient fluorescence emission.

(Solar Cell Element 3)

The solar cell element 3 is provided on an intersecting surface of the high refractive index material layer 2 that intersects the counter surface of the high refractive index material layer 2 which faces the low refractive index material layer 1 (i.e., on an end face of the high refractive index material layer 2). The solar cell element 3 generates electrical power upon receiving incident light. The solar cell element 3 needs only generate electrical power upon receiving light from the fluorescent material contained in the high refractive index material layer 2, and can also be configured to utilize, for power generation, light directly entering the solar cell element 3.

As the solar cell element 3, a publicly-known solar cell can be used, and examples of such a solar cell include, but are not limited to, an amorphous silicon (a-Si) solar cell, a polycrystalline silicon solar cell, a monocrystalline silicon solar cell, etc. The solar cell element 3 is attached to the end face of the high refractive index material layer 2 with a conventionally publicly-known transmissive adhesive, a stopper, etc. The size of the solar cell element 3 is not particularly limited, but it is preferable that the width of a light-receiving section of the solar cell element 3 be equal to the thickness of the high refractive index material layer 2. This allows the solar cell element 3 to efficiently receive light guided through the high refractive index material layer 2 to the end face. Besides, that surface of the solar cell element 3 which faces the light-collecting surface of the high refractive index material layer 2 may be covered with the high refractive index material layer 2, and that surface of the solar cell element 3 which faces away from the light-collecting surface of the high refractive index material layer 2 may be covered with the low refractive index material layer 1.

The solar cell module 10 is produced by first forming the low refractive index material layer 1 on the object 4 from a low refractive index material, and then forming the high refractive index material layer 2 by applying a high refractive index material onto the low refractive index material layer 1. At this point, the low refractive index material layer 1 and the high refractive index material layer 2 do not need to adhere completely to each other, and there may be an air layer interposed partially between the low refractive index material layer 1 and the high refractive index material layer 2. Then, the solar cell element 3 is provided in such a manner that the light-receiving surface of the solar cell element 3 is in contact with the end face of the high refractive index material layer 2 (attaching step).

The longer distance light is guided through the high refractive index material layer 2, the less efficiently the light is focused onto the solar cell element 3. Therefore, when the low refractive index material layer 1 and the high refractive index material layer 2 are formed by applying a low refractive index material and a high refractive index material over a wide range, it is preferable to position solar cell elements 3 in places so as to shorten the distance the light is guided.

Next, the way in which sunlight having entered the solar cell module 10 is guided through the high refractive index material layer 2 is described. When light from a high refractive index region enters a low refractive index region, the light is totally reflected, depending on the angle of incidence. For example, in a high refractive index material layer 2 having a refractive index of 1.5, light from the fluorescent material excited by sunlight will be emitted out of the high refractive index material layer 2 if the exciting light is incident on a surface of the high refractive index material layer 2 at an angle of 0° to approximately 41° (assuming that the angle of line normal to the surface is 0°). On the other hand, the light incident at an angle equal to or more than approximately 41° is guided through the high refractive index material layer 2 and totally reflected repeatedly at the interface between the high refractive index material layer 2 and the low refractive index material layer 1. In the case of use of such a high refractive index material layer 2 having a refractive index of 1.5, the ratio of the light guided through the high refractive index material layer 2 to the light emitted out of the high refractive index material layer 2 is approximately 75:25.

Such a solar cell module 10 as that shown in FIG. 1 was fabricated, and its power generation efficiency was examined. First, a low refractive index material layer 1, 100 μm in thickness, was formed by coating the south-facing wall of a building with a silica particle dispersion polymer having a refractive index of 1.321 and by curing the polymer with ultraviolet radiation. Next, a high refractive index material was prepared by dispersing, in bisphenol-A epoxy resin (AER-260, produced by Asahi Kasei Epoxy Co., Ltd) having a refractive index of 1.574, approximately 5% by weight of particles, 5 to 10 μm in diameter, of a rare-earth metal complex that emits light on exposure to ultraviolet radiation (such as a [Tb(bpy)2]C13 metal complex, a [Tb(terpy)2]C13 metal complex, or a [Eu(phen)2]C13 metal complex).

The high refractive index material thus prepared was applied onto the low refractive index material layer 1 and cured with ultraviolet radiation, whereby a high refractive index material layer 2, 200 μm in thickness, was formed. Then, a p-Si solar cell was attached to an end face of a laminated coating film constituted by the low refractive index material layer 1 and the high refractive index material layer 2. While electricity generated by irradiating the solar cell module 10 thus fabricated with sunlight was approximately 50 W per 10 m² of the laminated coating film, electricity generated by irradiating a conventional solar cell module laid all over a surface was approximately 20 W. It should be noted here that unlike the solar cell module of the present invention, which is irradiated with light focused, the conventional solar cell module is a type of solar cell module that is directly irradiated with sunlight.

As described above, the solar cell module 10 is configured such that the high refractive index material layer 2, which has a higher refractive index than the low refractive index material layer and contains a fluorescent material, is provided on the low refractive index material layer 1 provided on a surface of the object 4. Because these layers can be formed, for example, by coating the object 4, the solar cell module 10 can be suitably placed on a curved surface etc. without limitations of installation locations.

Furthermore, since the solar cell element 3 is provided on that end face of the high refractive index material layer 2 which intersects the light-collecting surface, the solar cell module 10 can be inexpensively produced which is small in area but sufficient in power generation efficiency. Additionally, because the refractive index relationship between the high refractive index material layer 2 and the low refractive index material layer 1 is under control, light from the fluorescent material excited by sunlight can be efficiently guided through the high refractive index material layer 2. Therefore, since the solar cell module 10 is installed by forming the layers by coating building walls, roof tiles, automobile bodies, etc., a highly efficient solar power generation system can be achieved.

(Solar Power Generation Device)

A solar power generation device according to the present invention includes such a solar cell module 10 as that described above. The solar power generation device according to the present invention may for example include a plurality of solar cell modules 10 and a storage cell in which output from the solar cell modules 10 is stored. Since the solar power generation device according to the present invention includes the solar cell modules 10, the solar power generation device can efficiently convert solar energy into electrical power on building walls, roof tiles, automobile bodies, etc.

### Embodiment 2

(Solar Cell Module 20)

Another embodiment of a solar cell module 20 according to the present invention is described below with reference to FIG. 2. FIG. 2 is a cross-sectional view showing the solar cell module 20. In the present embodiment, as shown in FIG. 2, the solar cell module 20 differs from the solar cell module 10 of Embodiment 1 in that a protective layer 21 having a lower refractive index than a high refractive index material layer 2 is provided on the high refractive index material layer 2. In the present embodiment, the features that distinguish the present embodiment from Embodiment 1 are described, and the other details are omitted. Meanwhile, an object 4 is present on a surface of a low refractive index material layer 1 opposite that surface of the low refractive index material layer 1 which is in contact with the high refractive index material layer 2.

(Protective Layer 21)

In the present embodiment, the solar cell module 20 includes, on the high refractive index material layer 2, the protective layer 21 having a lower refractive index than the high refractive index material layer 2. The protective layer 21 reflects light from the high refractive index material layer 2 at the interface between the protective layer 21 and the high refractive index material layer 2 due to the difference in refractive index, and protects the high refractive index material layer 2. The protective layer 21 is made of a material having a lower refractive index than the high refractive index material of which the high refractive index material layer 2 is made. As such a low refractive index material, it is possible to use the same material as the low refractive index material of which the low refractive index material layer 1 is made.

The protective layer 21 can be formed by coating the high refractive index material layer 2 with a material having a lower refractive index than the high refractive index material 2 (protective layer forming step). Alternatively, the protective layer 21 may be formed by forming, in advance, a layer of a material having a lower refractive index than the high refractive index material layer 2 and then attaching the layer onto the high refractive index material layer 2 with an adhesive or the like. Examples of a method for coating the high refractive index material layer 2 with the material having a lower refractive index than the high refractive index material layer 2 include the same method as the method for coating the object 4 with the low refractive index material.

It is preferable that the protective layer 21 have a thickness in the range of 1 to 10000 μm or, more preferably, in the range 100 to 1000 μm. This allows the high refractive index material layer 2 to be protected even in cases where the surface of the solar cell module 20 gets scratched. The protective layer 21 can also function as a light guide layer to guide part of light having propagated through the protective layer 21.

The solar cell module 20 is produced by first forming the low refractive index material layer 1 on the object 4 from a low refractive index material, and then forming the high refractive index material layer 2 by applying a high refractive index material onto the low refractive index material layer 1. Then, the protective layer 21 is formed by applying, onto the high refractive index material layer 2, a material having a lower refractive index than the high refractive index material layer 2, and then a solar cell element 3 is provided in such a manner that a light-receiving surface of the solar cell element 3 is in contact with an end face of the high refractive index material layer 2. It is also possible to first attach the solar cell element 3 to the high refractive index material layer 2 prior to the formation of the protective layer 21 and then form the protective layer 21 in such a manner as to cover the solar cell element 3.

Such solar cell module 20 as that shown in FIG. 2 was fabricated, and its power generation efficiency was examined. First, a low refractive index material layer 1, 100 μm in thickness, was formed by coating part of an automobile body with a silica particle dispersion polymer having a refractive index of 1.321 and then by curing the polymer with ultraviolet radiation. Next, a high refractive index material was prepared by dispersing, in fluorene-based epoxy resin (EX-1051, produced by Nagase 86 Co., Ltd.) having a refractive index of 1.634, approximately 5% by weight of particles, 5 to 10 μm in diameter, of a rare-earth metal complex that emits light on exposure to ultraviolet radiation (such as a [Tb(bpy)2]C13 metal complex, a [Tb(terpy)2]C13 metal complex, or a [Eu(phen)2]C13 metal complex).

The high refractive index material thus prepared was applied onto the low refractive index material layer 1 and cured with ultraviolet radiation, whereby a high refractive index material layer 2, 200 μm in thickness, was formed. Furthermore, a protective layer 21, 100 μm in thickness, was formed by coating the high refractive index material layer 2 with a silica particle dispersion polymer having a refractive index of 1.321, and then by curing the polymer with ultraviolet radiation. Then, a p-Si solar cell was attached to an end face of a laminated coating film constituted by the low refractive index material layer 1 and the high refractive index material layer 2. While electricity generated by irradiating the solar cell module 20 thus fabricated with sunlight was approximately 10 W per 10 m² of the laminated coating film, electricity generated by irradiating a conventional solar cell module laid all over a surface was approximately 5 W.

Since the solar cell module 20 is configured such that the high refractive index material layer 2 is protected by the protective layer 21, the high refractive index material layer 2 containing a fluorescent material can be prevented from deteriorating. Also, because the protective layer 21 can be formed by coating, as with the low refractive index material layer 1 and the high refractive index material layer, the solar cell module 20 can be suitably placed on a curved surface etc. without limitations of installation locations.

When the solar cell module 20 is installed on part of the body of an automobile, part of the paint on the automobile may be constituted by the low refractive index material layer 1, the high refractive index material layer 2, and the protective layer 21. Although the solar cell element 3 can be placed on the automobile body, the placement of the solar cell element 3 on an inconspicuous location, such as the ceiling, the boundary between the body and the window frame, and the interface between the front body and the front doors, makes it possible to use the solar cell module 20 without ruining the design of the automobile.

### Embodiment 3

(Solar Cell Module 30)

Another embodiment of a solar cell module 30 according to the present invention is described below with reference to FIG. 3. FIG. 3 is a cross-sectional view showing the solar cell module 30. In the present embodiment, as shown in FIG. 3, a solar cell element 34 differs in shape and placement from the solar cell element 3 of the solar cell module 10 in Embodiment 1. In the present embodiment, the features that distinguish the present embodiment from Embodiment 1 are described, and the other details are omitted. Meanwhile, an object 4 is present on a surface of a low refractive index material layer 1 opposite that surface of the low refractive index material layer 1 which is in contact with a high refractive index material layer 2.

In the solar cell module 30, the high refractive index material layer 32, which has a counter surface facing the low refractive index material layer 31, has its intersecting surface inclined with respect to the counter surface in such a manner that the high refractive index material layer 32 continuously becomes thinner from an end of that part of the high refractive index material layer 32 which overlaps the low refractive index material layer 31 toward an end of the high refractive index material layer 32 per se. That is, the high refractive index material layer 32 has a shape that becomes narrower toward the solar cell element 34.

Further, the solar cell element 34 includes a light-receiving surface that receives light from the high refractive index material layer 32, and the solar cell element 34 is attached to the high refractive index material layer 32 in such a manner that the light-receiving surface is in contact with the intersecting surface of the high refractive index material layer 32. The solar cell element 34 has its light-receiving surface inclined with respect to that surface of the solar cell element 34 which is in contact with an end face of the low refractive index material layer 1, in such a manner that the solar cell element 34 continuously becomes thicker from the surface of the solar cell element 34 which is in contact with the end face of the low refractive index material layer 1 toward the opposite surface. That is, the light-receiving surface is inclined in the same manner as the intersecting surface.

The solar cell element 34 is in contact with both the end face of the low refractive index material layer 31 and with the end face of the high refractive index material layer 32, and is covered with both the low refractive index material layer 31 and the high refractive index material layer 32. A protective layer 33 is provided on the high refractive index material layer 32.

The solar cell module 30 is produced by first attaching the solar cell element 34 onto the object 4, and then forming the low refractive index material layer 31 from a low refractive index material in such a manner that the end face of the low refractive index material layer 31 is in contact with that surface of the solar cell element 34 which intersects the surface of the low refractive index material layer 31 which is in contact with the object 4. Further, the high refractive index material layer 32 is formed by applying a high refractive index material onto the solar cell element 34 and onto the low refractive index material layer 31 in such a manner that the end face of the high refractive index material layer 32 is in contact with the light-receiving surface of the solar cell element 34. Next, the protective layer 33 is formed on the high refractive index material layer 32. Use of the solar cell module 30 thus fabricated brought about an approximately 20% increase in power generation efficiency as compared with the cases where the solar cell elements 3 was were placed as described in the other embodiments.

Since, in the solar cell module 30, the solar cell element and the high refractive index material layer 32 are configured in such a manner a surface of contact between the light-receiving surface of the solar cell element 34 and the high refractive index material layer 32 is large, the light receiving efficiency of the solar cell element is improved, whereby the power generation efficiency is further improved. Also, because the low refractive index material layer 31 and the high refractive index material layer 32 can be formed by coating, the solar cell module 30 can be suitably placed on a curved surface etc. without limitations of installation locations.

The present invention is not limited to the description of the embodiments above, but may be altered by a skilled person within the scope of the claims. An embodiment based on a proper combination of technical means disclosed in different embodiments is encompassed in the technical scope of the present invention.

The solar cell module according to the present invention is preferably configured to further include a protective layer, provided on the high refractive index material layer, which has a lower refractive index than the high refractive index material layer. In this way, since the solar cell module is configured such that the high refractive index material layer is protected by the protective layer, the high refractive index material layer can be prevented from deteriorating.

Further, the solar cell module according to the present invention is preferably configured such that: the intersecting surface is inclined with respect to the counter surface in such a manner that the high refractive index material layer continuously becomes thinner toward an end of the high refractive index material layer; and the solar cell element is provided on the high refractive index material layer by joining a light-receiving surface of the solar cell element and the intersecting surface of the high refractive index material layer to each other.

With such a configuration as that described above, since, in the solar cell module, the solar cell element and the high refractive index material layer are configured in such a manner a surface of contact between the light-receiving surface of the solar cell element and the high refractive index material layer is large, the light receiving efficiency of the solar cell element is improved, whereby the power generation efficiency is further improved.

Further, the solar cell module according to the present invention is preferably configured such that: the low refractive index material layer is formed by coating the object with a low refractive index material; and the high refractive index material layer is formed by coating the low refractive index material layer with a high refractive index material having a higher refractive index than the low refractive index material and containing a fluorescent material.

With the above configuration, because the low refractive index material layer and the high refractive index material layer can be formed by coating the object with the materials, the solar cell module can be suitably placed on a curved surface etc. without limitations of installation locations.

Further, the solar cell module according to the present invention is preferably configured such that the protective layer is formed by coating the high refractive index material layer with a material having a lower refractive index than the high refractive index material layer. In this way, because the protective layer, which prevents the high refractive index material layer from deteriorating, can be formed by coating, as with the low refractive index material layer and the high refractive index material layer, the solar cell module can be suitably placed on a curved surface etc. without limitations of installation locations.

Further, the method according to the present invention is preferably configured to further include a protective layer forming step of forming a protective layer by coating the high refractive index material layer with a material having a lower refractive index than the high refractive index material. In this way, because the protective layer, which prevents the high refractive index material layer from deteriorating, can be formed by coating, as with the low refractive index material layer and the high refractive index material layer, the solar cell module can be suitably placed on a curved surface etc. without limitations of installation locations.

### INDUSTRIAL APPLICABILITY

Since the present invention can provide a solar cell module that has a high degree of freedom in design and that can be placed on a curved surface etc. without limitations of installation locations, the present invention can be suitably used as a solar power generation system on building walls, roof tiles, automobile bodies, etc.

### REFERENCE SIGNS LIST

1, 31 Low refractive index material layer
2, 32 High refractive index material layer
3, 34 Solar cell element
4 Object
10, 20, 30 Solar cell module

1. A solar cell module comprising:
a low refractive index material layer provided on an object;
a high refractive index material layer, provided on the low refractive index material layer, which has a higher refractive index than the low refractive index material layer and which contains a fluorescent material; and
a solar cell element provided on an intersecting surface of the high refractive index material layer, the intersecting surface intersecting a counter surface of the high refractive index material layer, the counter surface facing the low refractive index material layer.

2. The solar cell module as set forth in claim 1, further comprising a protective layer, provided on the high refractive index material layer, which has a lower refractive index than the high refractive index material layer.

3. The solar cell module as set forth in claim 1, wherein:
the intersecting surface is inclined with respect to the counter surface in such a manner that the high refractive index material layer continuously becomes thinner toward an end of the high refractive index material layer; and
the solar cell element is provided on the high refractive index material layer by joining a light-receiving surface of the solar cell element and the intersecting surface of the high refractive index material layer to each other.

4. The solar cell module as set forth in claim 1, wherein:
the low refractive index material layer is formed by coating the object with a low refractive index material; and
the high refractive index material layer is formed by coating the low refractive index material layer with a high refractive index material having a higher refractive index than the low refractive index material and containing a fluorescent material.

5. The solar cell module as set forth in claim 2, wherein the protective layer is formed by coating the high refractive index material layer with a material having a lower refractive index than the high refractive index material layer.

6. A solar power generation device comprising a solar cell module as set forth in claim 1.

7. A method for producing a solar cell module, the method comprising:
a low refractive index material layer forming step of forming a low refractive index material layer by coating an object with a low refractive index material;
a high refractive index material layer forming step of forming a high refractive index material layer by coating the low refractive index material layer with a high refractive index material having a higher refractive index than the low refractive index material and containing a fluorescent material; and
an attaching step of attaching a solar cell element to an intersecting surface of the high refractive index material layer, the intersecting surface intersecting a counter surface of the high refractive index material layer, the counter surface facing the low refractive index material layer.

8. A method for producing a solar cell module, the method comprising:
an attaching step of attaching a solar cell element onto an object;
a low refractive index material layer forming step of, subsequent to the attaching step, forming a low refractive index material layer by coating the object with a low refractive index material; and
a high refractive index material layer forming step of forming a high refractive index material layer by coating the low refractive index material with a high refractive index material having a higher refractive index than the low refractive index material and containing a fluorescent material,
in the low refractive index material layer forming step, the low refractive index material layer being formed in such a manner that an intersecting surface of the solar cell element and an end face of the low refractive index material are in contact with each other, the intersecting surface intersecting that surface of the solar cell element which is in contact with the object, in the high refractive index material layer forming step, the high refractive index material layer being formed in such a manner that a light-receiving surface of the solar cell element and an end face of the high refractive index material layer are in contact with each other.

9. The method as set forth in claim 7, further comprising a protective layer forming step of forming a protective layer by coating the high refractive index material layer with a material having a lower refractive index than the high refractive index material.
